(19) United States
(12) Patent Application Publication
(10) Pub. No.: US 2009/0246955 A1
(43) Pub. Date: Oct. 1, 2009

(54) WAFER PROCESSING METHOD AND WAFER PROCESSING APPARATUS

(76) Inventors: Masayuki Kanazawa, Tokyo (JP); Tomoo Hayashi, Tokyo (JP); Shigeharu Arisa, Tokyo (JP)

Correspondence Address: CHRISTIE, PARKER & HALE, LLP, PO BOX 7068, PASADENA, CA, 91109-7068, US

(21) Appl. No.: 12/332,730

(22) Filed: Dec. 11, 2008

(30) Foreign Application Priority Data
Mar. 26, 2008 (JP) 2008-080363

(51) Int. Cl. H01L 21/306; H01L 21/461; B24B 7/20

(52) U.S. Cl. 438/692; 156/345.12; 451/287; 257/E21.483

(57) ABSTRACT

A wafer processing method is provided comprising the steps of: holding a wafer (20) having devices formed on its front surface (21) so that a back surface (22) of the wafer is exposed; grinding the back surface of the wafer to form a brittle fracture layer (Z) on the back surface; and polishing the back surface of the wafer entirely so that the brittle fracture layer remains partially. It is possible to improve the strength of the wafer and reduce its surface roughness while allowing utilization of a gettering effect. It is also preferable to remove only an outermost layer of the back surface of the wafer. Further, it is preferable that the wafer is polished by at least one of wet polishing, dry polishing, wet etching and dry etching.

### BACKGROUND OF THE INVENTION

1. Field of the Invention

The present invention relates to a wafer processing method for processing a wafer having devices formed on its front surface and a wafer processing apparatus for implementing such method.

2. Description of the Related Art

In the field of semiconductor manufacturing, wafers tend to become larger year by year and the wafers are made thinner in order to increase packing density. In order to make a semiconductor wafer thinner, a backgrinding process for grinding a back surface of the wafer is carried out. In the backgrinding process, a surface protection film is applied to a front surface of the wafer for protecting semiconductor devices formed on the front surface of the wafer.

As a result of the backgrinding process, a brittle fracture layer (mechanically damaged layer) is formed on an outermost layer of the back surface of the wafer. This brittle fracture layer may reduce the strength of the wafer and increase its surface roughness. Therefore, typically, after the backgrinding process, the back surface of the wafer is polished to remove the brittle fracture layer, so as to prevent the reduction of the strength of the wafer and to reduce its surface roughness.

The brittle fracture layer formed by the backgrinding process may be utilized for creating a gettering effect. This gettering effect is an effect for gathering impurities mainly comprised of heavy metal, which are included in the semiconductor wafer during the manufacturing process of semiconductor chips, in a distortion field formed outside a device forming region where devices such as electronic circuits and the like are formed in the semiconductor chips, so as to clean the device forming region, wherein the mechanically damaged region or, for example, the brittle fracture layer is utilized as the distortion field. It is thought that, thanks to this gettering effect, impurities do not exist in the device forming region, malfunctions such as crystal defects and degradation of electrical properties can be inhibited and, further, the semiconductor chips can be stabilized and their performance can be improved. For example, Japanese Unexamined Patent Publication No. 2005-277116 discloses a technique for obtaining the gettering effect.

If the wafer is polished so that the brittle fracture layer is removed completely for preventing problems such as the reduction of the strength and the like, the gettering effect cannot be utilized. In other words, there is a trade-off between improvement, such as an increase in strength and reduction of the surface roughness of the wafer and the utilization of the gettering effect.

The present invention has been made in view of such circumstances and it is an object of the present invention to provide a wafer processing method that can intend to improve strength and reduce surface roughness of the wafer while allowing utilization of a gettering effect and a wafer processing apparatus for implementing such method.

### SUMMARY OF THE INVENTION

In order to accomplish the above object, according to a first aspect, there is provided a wafer processing method comprising the steps of: holding a wafer having devices formed on its front surface so that a back surface of the wafer is exposed; grinding said back surface of said wafer to form a brittle fracture layer on said back surface; and polishing said back surface of said wafer entirely so that said brittle fracture layer remains partially.

Thus, in the first aspect, because the brittle fracture layer created in the grinding step partially remains, the gettering effect can be utilized so as to stabilize the intended properties and improve the performance of semiconductor chips. Further, because the back surface of the wafer is polished, in comparison with the case in which the wafer is only ground but not polished, strength of the wafer can be increased and, at the same time, surface roughness and warpage of the wafer can be reduced.

According to a second aspect, in the first aspect, only an outermost layer of said back surface of said wafer is removed in the polishing step.

Thus, in the second aspect, because only the outermost layer is polished, the brittle fracture layer is not removed completely and, therefore, the gettering effect can be effectively utilized.

According to a third aspect, in the first or second aspect, said wafer is polished by at least one of wet polishing, dry polishing, wet etching and dry etching.

Thus, in the third aspect, it is possible to intend to improve the strength of the wafer and reduce its surface roughness in a relatively simple manner while allowing the utilization of the gettering effect.

According to a fourth aspect, there is provided a wafer processing apparatus comprising: holding means for holding a wafer having devices formed on its front surface so that a back surface of the wafer is exposed; grinding means for grinding said back surface of said wafer; and polishing means for polishing said back surface of said wafer entirely so that a brittle fracture layer remains partially.

Thus, in the fourth aspect, because the brittle fracture layer created in the grinding step partially remains, the gettering effect can be utilized so as to stabilize the intended properties and improve performance of semiconductor chips. Further, because the back surface of the wafer is polished, in comparison with the case in which the wafer is only ground, but is not polished, strength of the wafer can be increased and, at the same time, surface roughness and warpage of the wafer can be reduced.

According to a fifth aspect, in the fourth aspect, said polishing means removes only an outermost layer of said back surface of said wafer by polishing.

Thus, in the fifth aspect, because only the outermost layer is polished, the brittle fracture layer is not removed completely and, therefore, the gettering effect can be effectively utilized.

According to a sixth aspect, in the fourth or fifth aspect, said polishing means performs at least one of wet polishing, dry polishing, wet etching and dry etching.

Thus, in the sixth aspect, it is possible to improve the strength of the wafer and reduce its surface roughness in a relatively simple manner while allowing the utilization of the gettering effect.

These and other objects, features and advantages of the present invention will be more apparent from the detailed description of the typical embodiments of the present invention illustrated in the accompanying drawings.

### BRIEF DESCRIPTION OF THE DRAWINGS

FIG. 1 is a schematic plan view of a wafer processing apparatus to which a wafer processing method according to the present invention is applied;

FIG. 2 is a partial cross-sectional view of a polishing unit;

FIG. 3 is a partial cross-sectional view of a wafer after grinding by the wafer processing apparatus of the present invention; and

FIG. 4 is a partial cross-sectional view of a wafer after polishing by the wafer processing apparatus of the present invention.

### DETAILED DESCRIPTION OF THE PREFERRED EMBODIMENTS

Hereinafter, embodiments of the present invention will be described in detail with reference to the accompanying drawings. Throughout the several views, like elements are designated by like reference numerals. For ease of understanding, the scale of these drawings is changed appropriately.

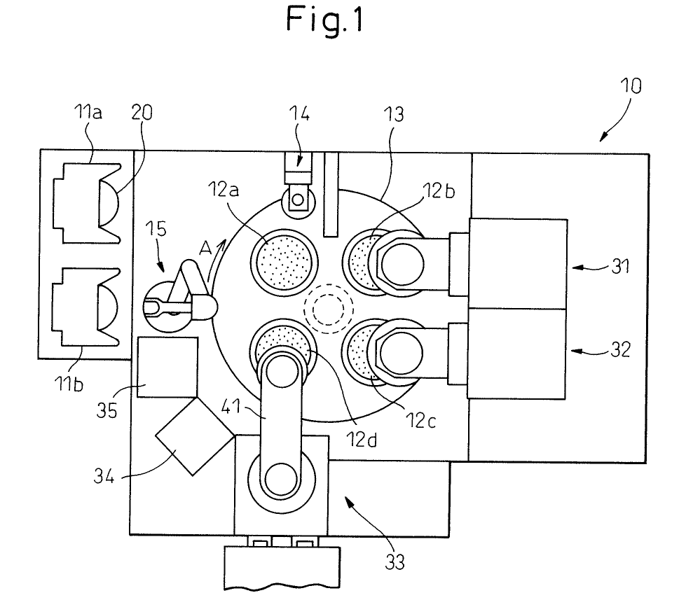

FIG. 1 is a schematic plan view of a wafer processing apparatus to which a wafer processing method according to the present invention is applied. It is assumed that a cassette 11a supplies a plurality of wafers 20 to wafer processing apparatus 10, wherein, in each of the plurality of wafers 20, a plurality of circuit patterns 19 are formed on a front surface 21 and front surface 21 is protected by a surface protection film 3.

Wafer processing apparatus 10 illustrated in FIG. 1 includes: a turntable 13 that comprises four chuck section 12a-12d and performs index rotation; a washing unit 14 for washing four chuck sections 12a-12d; and a transfer robot 15 for carrying wafers 20.

Further, as illustrated in FIG. 1, in wafer processing apparatus 10, a rough grinding unit 31, a finish grinding unit 32 and a polishing unit 33 are arranged along turntable 13 in this order. Rough grinding unit 31 performs rough grinding of a back surface 22 of wafer 20 by means of a rough grindstone (not illustrated in the figure), and a finish grinding unit 32 performs finish grinding of back surface 22 by means of a finish grindstone (not illustrated in the figure).

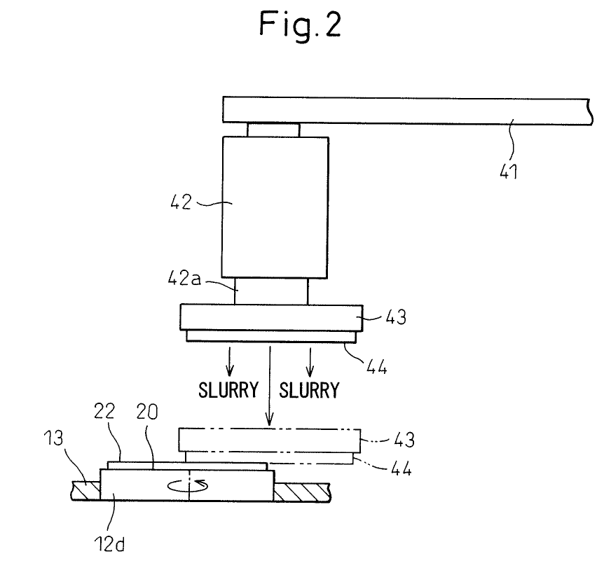

FIG. 2 is a partial cross-sectional view of polishing unit 33. As illustrated in FIG. 2, a motor 42 is suspended from a tip of an arm 41 of polishing unit 33. Then, a polishing head 43 is rotatably attached to an output shaft 42a of motor 42. Further, a polishing cloth 44 of polishing head 43 can discharge slurry as needed.

During the polishing process, polishing head 43 and chuck section 12a rotate in directions opposite to each other and, then, polishing head 43 descends integrally with arm 41 in the thickness direction of wafer 20. As a result, back surface 22 of wafer 20 held by chuck section 12d is polished entirely evenly. Polishing unit 33 can perform wet etching by discharging the slurry from polishing cloth 44 or, alternatively, it can perform dry etching without utilizing the slurry.

Referring to FIG. 1 again, a wet etching unit 34 and dry etching unit 35 are disposed between transfer robot 15 and polishing unit 33. Wet etching unit 34 etches back surface 22 of wafer 20 by using a chemical agent. On the other hand, dry etching unit 35 etches back surface 22 of wafer 20 by using a fluorine-based gas.

Hereinafter, an operation of wafer processing apparatus 10 of the present invention will be described. First, transfer robot 15 draws out one wafer 20 from cassette 11a and transfers it to chuck section 12a.

Chuck section 12a sucks and holds wafer 20 so that its back surface 22 faces upward. Then, washing unit 14 washes wafer 20 on chuck section 12a. After that, turntable 13 performs index rotation so as to move chuck section 12a to rough grinding unit 31. At this time, transfer robot 15 transfers another wafer 20 to another chuck section 12d and similar processes are performed sequentially. However, these processes are publicly known and, therefore, not described here.

Rough grinding unit 31 performs the rough grinding of back surface 22 of wafer 20 by using the rough grindstone (not illustrated in the figure) in a publicly known manner. Then, turntable 13 performs the index rotation so as to move chuck section 12a from rough grinding unit 31 to finish grinding unit 32. Finish grinding unit 31 performs the finish grinding of back surface 22 of wafer 20 by using the finish grindstone (not illustrated in the figure) in a publicly known manner.

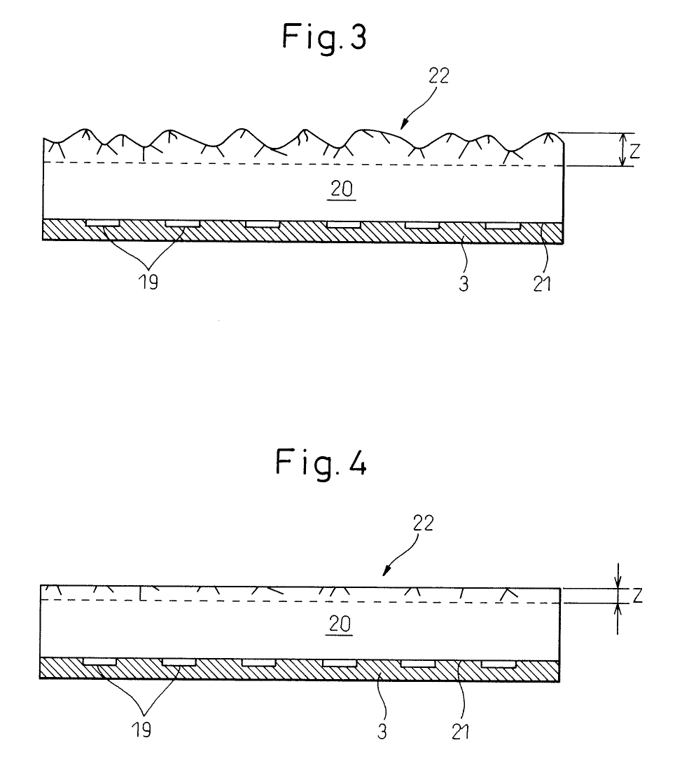

FIG. 3 is a partial cross-sectional view of wafer 20 after the grinding process. After the grinding process by rough grinding unit 31 and finish grinding unit 32, as shown in FIG. 3, back surface 22 of wafer 20 is relatively rough and a brittle fracture layer Z is formed on back surface 22. In brittle fracture layer Z, numerous fine cracks, fractures or internal distortions (hereinafter referred to as “cracks and the like”) are formed and brittle fracture layer Z including these cracks and the like are used for obtaining a gettering effect. More specifically, brittle fracture layer Z including the cracks and the like gathers impurities mainly comprised of heavy metals and, as a result, the impurities are not likely to exist in circuit patterns 19.

Referring to FIG. 1 again, after the grinding process, turntable 13 performs the index rotation again so as to move chuck section 12a from finish grinding unit 32 to polishing unit 33. As shown in FIG. 2, polishing unit 33 performs wet polishing by discharging the slurry from polishing cloth 44. After the wet polishing is finished, the holding effect of chuck section 12a is terminated. Then, transfer robot 15 transfers wafer 20 from chuck section 12a to cassette 11b.

FIG. 4 is a partial cross-sectional view of wafer 20 after the polishing process. As shown in FIG. 4, in the present invention, polishing head 43 removes only an outermost layer of back surface 22 to the extent that back surface 22 becomes flat entirely. Therefore, brittle fracture layer Z is not removed completely but a portion of brittle fracture layer Z remains on back surface 22.

As described above, in the present invention, because brittle fracture layer Z created by the grinding process remains partially, the impurities mainly comprised of heavy metals can be gathered in the crack and the like in brittle fracture layer Z, so that the impurities are not likely to exist in circuit patterns 19. As a result, it is possible to stabilize the intended properties of circuit patterns 19 and improve their performance. In other words, in the present invention, the gettering effect can be effectively utilized.

Further, in the present invention, because back surface 22 of wafer 20 is polished, so that the cracks and the like in brittle fracture layer Z can be reduced and, as a result, strength of wafer 20 can be increased and, at the same time, surface roughness of back surface 22 can be reduced. Still further, the grindstone can restore warped wafers to original condition to some extent. Here, wafer 20 may also be dry polished without discharging the slurry from polishing cloth 44 and it is to be understood that a similar effect can be obtained also in this case.

Alternatively, in place of polishing unit 33, wet etching unit 34 or dry etching unit 35 may be used to etch back surface 22 of wafer 20. In this case, the etching effect on back surface 22 works approximately similarly to the polishing of back surface 22 and, therefore, an effect similar to the above-mentioned one can be obtained.

While the present invention has been described with reference to the typical embodiments, those skilled in the art can understand that the changes described above and other various changes, omissions or additions can be made without departing from the scope of the present invention.

1. A wafer processing method comprising the steps of:
holding a wafer having devices formed on its front surface so that a back surface of the wafer is exposed;
grinding said back surface of said wafer to form a brittle fracture layer on said back surface; and
polishing said back surface of said wafer entirely so that said brittle fracture layer remains partially.

2. A wafer processing method according to claim 1, wherein only an outermost layer of said back surface of said wafer is removed in the polishing step.

3. A wafer processing method according to claim 1 or 2, wherein said wafer is polished by at least one of wet polishing, dry polishing, wet etching and dry etching.

4. A wafer processing apparatus comprising:
holding means for holding a wafer having devices formed on its front surface so that a back surface of the wafer is exposed;
grinding means for grinding said back surface of said wafer; and
polishing means for polishing said back surface of said wafer entirely so that a brittle fracture layer remains partially.

5. A wafer processing apparatus according to claim 4, wherein said polishing means removes only an outermost layer of said back surface of said wafer by polishing.

6. A wafer processing apparatus according to claim 4 or 5, wherein said polishing means performs at least one of wet polishing, dry polishing, wet etching and dry etching.
